(19) United States
(12) Patent Application Publication
(10) Pub. No.: US 2026/0083001 A1
(43) Pub. Date: Mar. 19, 2026

(54) SEMICONDUCTOR STORAGE DEVICE

(71) Applicant: Kioxia Corporation, Tokyo (JP)

(72) Inventor: Kosuke AWAGA, Yokohama Kanagawa (JP)

(73) Assignee: Kioxia Corporation, Tokyo (JP)

(21) Appl. No.: 19/070,660

(22) Filed: Mar. 5, 2025

(30) Foreign Application Priority Data
Sep. 13, 2024 (JP) 2024-159355

(51) Int. Cl. H01L 25/16; H01L 23/00; H01L 23/367; H10B 80/00

(52) U.S. Cl. CPC H10W 90/00; H10B 80/00; H10W 40/22; H10W 90/736

(57) ABSTRACT

A semiconductor storage device according to an embodiment includes a housing, a board, a first electronic component, and a second electronic component. The housing includes a first member and a second member. The first member has a first wall and an opening. The first wall faces the first electronic component when viewed from a first direction. The opening faces the second electronic component. The first direction is a thickness direction of the board. The second member has a main body portion and a support portion. The main body portion covers the second electronic component at a position further away from the board than the first wall. The main body portion includes one or more protrusions protruding toward a side opposite to the second electronic component. The support portion is connected to the first member. The support portion supports the main body portion.

### CROSS-REFERENCE TO RELATED APPLICATION

Priority is claimed on Japanese Patent Application No. 2024-159355, filed Sep. 13, 2024, the content of which is incorporated herein by reference.

### FIELD

An embodiment of the present invention relates to a semiconductor storage device.

### BACKGROUND ART

A semiconductor storage device including a housing, a board housed in the housing, and an electronic component mounted on the board is known.

### BRIEF DESCRIPTION OF THE DRAWINGS

FIG. 1 is a perspective view showing a semiconductor storage device of a first embodiment.

FIG. 2 is a partially-exploded perspective view showing the semiconductor storage device of the first embodiment.

FIG. 3 is an exploded perspective view showing a housing of the first embodiment.

FIG. 4 is a plan view showing the semiconductor storage device of the first embodiment.

FIG. 5 is a perspective view for explaining a second cover member of the first embodiment.

FIG. 6 is another perspective view for explaining the second cover member of the first embodiment.

FIG. 7 is a cross-sectional view taken along line F7-F7 of the semiconductor storage device shown in FIG. 1.

FIG. 8 is a cross-sectional view taken along line F8-F8 of the semiconductor storage device shown in FIG. 1.

FIG. 9 is a plan view showing the semiconductor storage device of the first embodiment.

FIG. 10 is a cross-sectional view showing a semiconductor storage device of a first modified example of the first embodiment.

FIG. 11 is a cross-sectional view showing a semiconductor storage device of a second modified example of the first embodiment.

FIG. 12 is a cross-sectional view showing a semiconductor storage device of a third modified example of the first embodiment.

FIG. 13 is a cross-sectional view showing a semiconductor storage device of a fourth modified example of the first embodiment.

FIG. 14 is a perspective view for explaining a second cover member of a second embodiment.

FIG. 15 is a perspective view showing the second cover member of the second embodiment.

FIG. 16 is another perspective view for explaining the second cover member of the second embodiment.

FIG. 17 is a perspective view for explaining a second cover member of a third embodiment.

FIG. 18 is a perspective view showing the second cover member of the third embodiment.

FIG. 19 is another perspective view for explaining the second cover member of the third embodiment.

### DETAILED DESCRIPTION

A semiconductor storage device according to an embodiment includes a housing, a board, a first electronic component, and a second electronic component. The board is in the housing. The board has a first surface. The first electronic component is on the first surface. The second electronic component is on the first surface. The second electronic component has a height larger than a height of the first electronic component from the first surface. The housing includes a first member and a second member. The first member has a first wall and an opening. The first wall faces the first electronic component when viewed from a first direction. The opening faces the second electronic component when viewed from the first direction. The first direction is a thickness direction of the board. The second member has a main body portion and a support portion. The main body portion covers the second electronic component at a position further away from the board than the first wall. The main body portion includes one or more protrusions protruding toward a side opposite to the second electronic component. The support portion is connected to the first member. The support portion supports the main body portion.

Hereinafter, a semiconductor storage device of an embodiment will be described with reference to the drawings. In the following description, components having the same or similar functions will be denoted by the same reference signs. Also, duplicate description of the components may be omitted. In the present application, terms are defined as follows. “Parallel”, “orthogonal”, or “the same” may include a case of “substantially parallel”, “substantially orthogonal”, or “substantially the same”. “Connection” is not limited to a case in which two elements are directly connected, and may include a case in which two elements are connected with another element interposed therebetween. Also, “connection” is not limited to a case of being mechanically connected, and may also include a case of being electrically connected. “Facing” and “overlapping” are not limited to a case in which two elements directly face each other, and may also include a case in which two elements face each other with another element interposed therebetween.

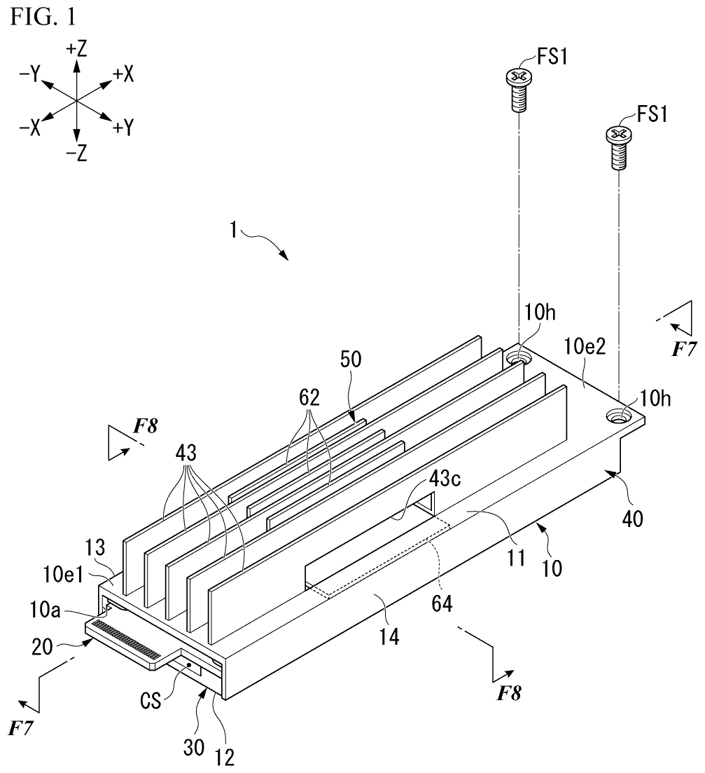

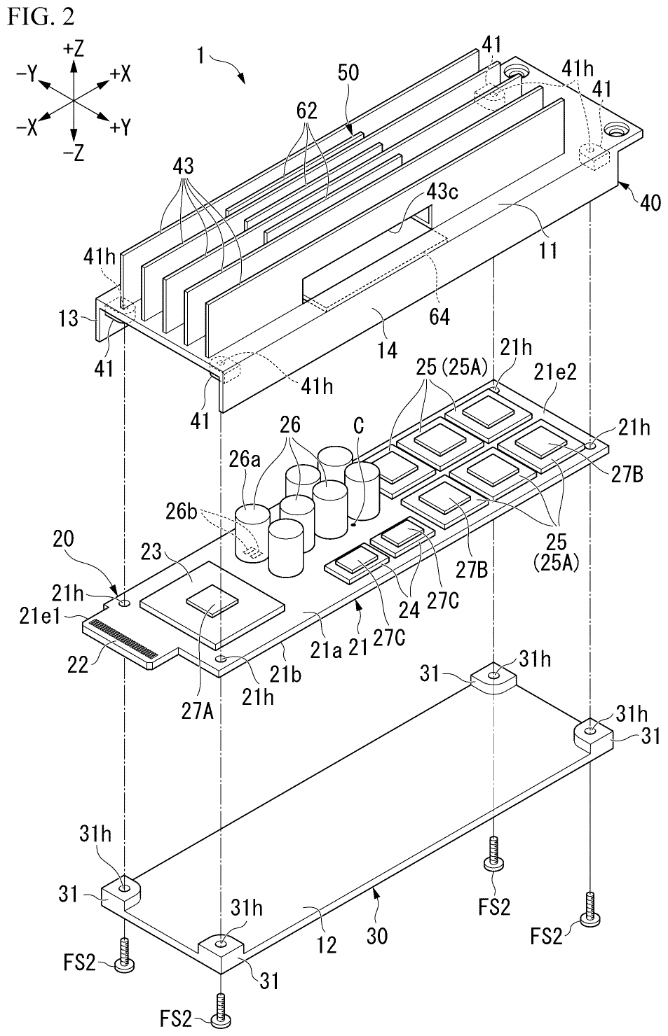

In the present application, a +X direction, a −X direction, a +Y direction, a −Y direction, a +Z direction, and a −Z direction will be defined as follows. The +X direction, the −X direction, the +Y direction, and the −Y direction are directions parallel to a first surface 21a of a board 21 to be described later (refer to FIG. 2). The +X direction is a direction from a first end part 10e1 to a second end part 10e2 of a housing 10 to be described later (refer to FIG. 1). The −X direction is a direction opposite to the +X direction. In a case in which the +X direction and the −X direction do not need to be distinguished from each other, they will be simply referred to as “X direction”. The +Y direction and the −Y direction are directions intersecting (for example, orthogonal to) the X direction. The +Y direction is a direction from a first side wall 13 to a second side wall 14 of the housing 10 to be described later (refer to FIG. 1). The −Y direction is a direction opposite to the +Y direction. In a case in which the +Y direction and the −Y direction do not need to be distinguished from each other, they will be simply referred to as “Y direction”. The +Z direction and the −Z direction are directions intersecting (for example, orthogonal to) the X direction and the Y direction. The +Z direction is a direction from a second main wall 12 to a first main wall 11 of the housing 10 to be described later (refer to FIG. 1). The −Z direction is a direction opposite to the +Z direction. In a case in which the +Z direction and the −Z direction do not need to be distinguished from each other, they will be simply referred to as “Z direction”. The Z direction is a thickness direction of the board 21. The Z direction is an example of a “first direction”. The Y direction is an example of a “second direction”. The X direction is an example of a “third direction”.

### First Embodiment

### <1. Overall Configuration of Semiconductor Storage Device>

A semiconductor storage device 1 of a first embodiment will be described with reference to FIGS. 1 to 9. The semiconductor storage device 1 is, for example, a storage device such as a solid state drive (SSD). The semiconductor storage device 1 is connected to a host device. The semiconductor storage device 1 is used as a storage device for the host device. The host device may be a personal computer, a mobile device, a video recorder, an in-vehicle device, or the like. The host device is not limited to these examples.

FIG. 1 is a perspective view showing the semiconductor storage device 1. The semiconductor storage device 1 includes, for example, a housing 10 and a board unit 20. Here, the board unit 20 will be described first.

### <2. Board Unit>

FIG. 2 is a partially-exploded perspective view showing the semiconductor storage device 1. The board unit 20 is an assembly. Components including circuits are mounted on the assembly. The board unit 20 has, for example, a board 21, a connection connector 22, a controller 23, a plurality of dynamic random access memories (DRAMs) 24, a plurality of NAND flash memories 25 (hereinafter referred to as “NANDs 25”), and a plurality of capacitors 26.

The board 21 is a plate member extending in the X direction and the Y direction. The board 21 is a printed circuit board. The board 21 includes an insulating base material and a wiring pattern provided on the insulating base material. The board 21 has a first surface 21a and a second surface 21b positioned on a side opposite to the first surface 21a. The first surface 21a extends in the X direction and the Y direction. The first surface 21a is a surface facing in the +Z direction. The second surface 21b extends in the X direction and the Y direction. The second surface 21b is a surface facing in the −Z direction.

The board 21 has a first end part 21e1 and a second end part 21e2 as end parts in a longitudinal direction (X direction) of the board 21. The first end part 21e1 is an end part of the board 21 on the side in the −X direction. The second end part 21e2 is an end part of the board 21 on the side in the +X direction. Each of the first end part 21e1 and the second end part 21e2 has a through hole 21h. The through hole 21h penetrates the board 21 in the Z direction. A fastening member FS2 to be described later is inserted through the through hole 21h.

The connection connector 22 is a connection portion connectable to a connector of the host device. The connection connector 22 includes a plurality of metal terminals connectable to a connector of the host device. The connection connector 22 is provided, for example, at the first end part 21e1 of the board 21. The connection connector 22 is exposed to the outside of the housing 10 through an opening 10a of the housing 10 (refer to FIG. 1).

The controller 23 is a component that is configured to comprehensively control the entirety of the semiconductor storage device 1. The controller 23 is, for example, a semiconductor package. The semiconductor package includes a system on a chip (SoC). In the chip (SoC), for example, a host interface circuit for the host device, a control circuit configured to control the plurality of NANDs 25, and the like are integrated into one semiconductor chip. The controller 23 is mounted on, for example, the first surface 21a of the board 21. In the X direction, the controller 23 is disposed between a center C of the board 21 in the X direction and the first end part 21e1 of the board 21. The controller 23 is a heat-generating component whose temperature becomes higher during operation of the semiconductor storage device 1 than each of the DRAM 24 and the NAND 25. The controller 23 is an example of a “fourth electronic component”.

Note that, the controller 23 may be mounted on the second surface 21b of the board 21 instead of the first surface 21a of the board 21. The “fourth electronic component” is not limited to the controller 23. The “fourth electronic component” may be, instead of the controller 23, a power supply circuit component, a power conversion component, or an electronic component with other functions. The “fourth electronic component” may be a power supply circuit component, a power conversion component, or an electronic component with other functions in addition to the controller 23. The power supply circuit component is, for example, a power management IC (PMIC). The power conversion component is, for example, a DC-DC converter.

The plurality of DRAMs 24 are data buffers. The data buffer temporarily stores write target data received from the host device, read target data read from the NAND 25, and the like. The plurality of DRAMs 24 are mounted on, for example, the first surface 21a of the board 21. The plurality of DRAMs 24 are disposed between the controller 23 and the plurality of NANDs 25 in the X direction. The plurality of DRAMs 24 are adjacent to the plurality of capacitors 26 in the Y direction. For example, the plurality of DRAMs 24 are disposed on the side in the +Y direction with respect to the plurality of capacitors 26. Each of the plurality of DRAMs 24 is an example of a “third electronic component”.

Note that, the number of DRAMs 24 may be one. The DRAM 24 may be provided inside the controller 23 as a part of the controller 23 instead of being provided as a separate part from the controller 23. The “third electronic component” is not limited to the DRAM 24. The “third electronic component” may be, instead of the DRAM 24, a power supply circuit component, a power conversion component, or an electronic component with other functions. The “third electronic component” may be a power supply circuit component, a power conversion component, or an electronic component with other functions in addition to the DRAM 24. The power supply circuit component is, for example, a PMIC. The power conversion component is, for example, a DC-DC converter.

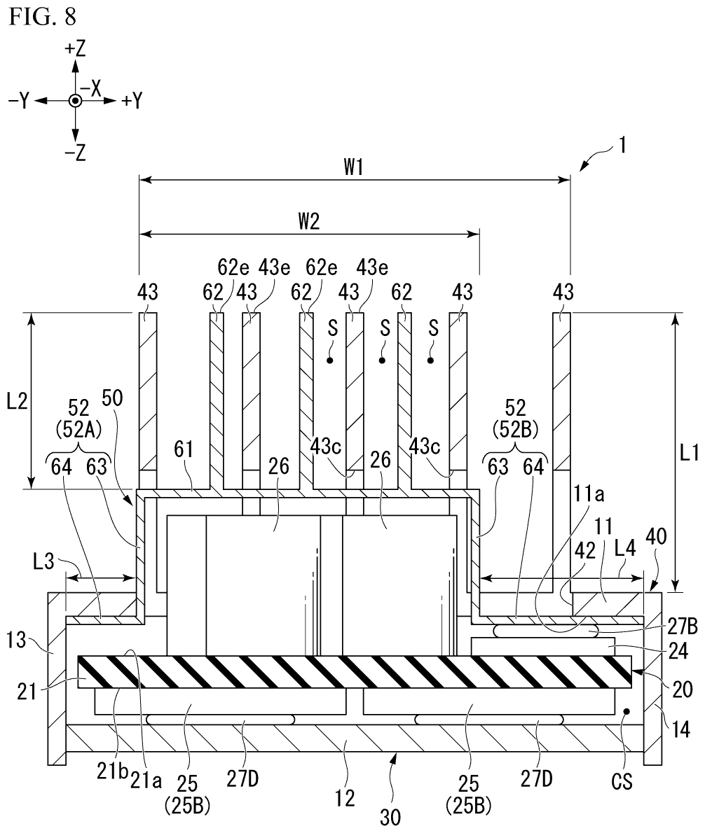

The NAND 25 is a semiconductor package that includes a nonvolatile semiconductor memory chip. The plurality of NANDs 25 include, for example, a plurality of NANDs 25A and a plurality of NANDs 25B (refer to FIG. 8). The plurality of NANDs 25A are mounted on the first surface 21a of the board 21. The plurality of NANDs 25B are mounted on the second surface 21b of the board 21. The plurality of NANDs 25A are thermally connected to the first main wall 11 of the housing 10 via a heat conductive member 27B. The plurality of NANDs 25B are thermally connected to the second main wall 12 of the housing 10 via a heat conductive member 27D (refer to FIG. 8).

In the X direction, the plurality of NANDs 25 are disposed between the center C of the board 21 in the X direction and the second end part 21e2 of the board 21. The NAND 25 is a heat-generating component with a higher priority for heat dissipation compared to the DRAM 24. The NAND 25 is a heat-generating component whose temperature becomes higher during operation of the semiconductor storage device 1 than the DRAM 24. The NAND 25 is an example of a “first electronic component”.

Note that, the number of NANDs 25 may be one. The “first electronic component” is not limited to the NAND 25. The “first electronic component” may be other types of semiconductor memory instead of the NAND 25, or may be an electronic component having a function different from that of a semiconductor memory. The “first electronic component” may be other types of semiconductor memory in addition to the NAND 25, or may be an electronic component having a function different from that of a semiconductor memory. Other types of semiconductor memory include, for example, a NOR type memory, a magnetoresistive random access memory (MRAM), a resistive memory, or the like.

The capacitor 26 is one of the components electrically connected to the board 21. The capacitor 26 assumes a power backup function for the purpose of data protection in the event of, for example, an unexpected power cutoff. In the first embodiment, the capacitor 26 supplies power to the controller 23, the plurality of DRAMs 24, and the plurality of NANDs 25 over a certain period of time when the power supply from the host device is unexpectedly cut off.

The plurality of capacitors 26 are mounted on the first surface 21a of the board 21. The plurality of capacitors 26 are disposed between the controller 23 and the plurality of NANDs 25 in the X direction. The capacitor 26 has a larger height from the first surface 21a of the board 21 compared to each of the controller 23, the DRAM 24, and the NAND 25. The capacitor 26 has, for example, a cylindrical component main body 26a and two terminals 26b connected to the board 21. In the first embodiment, the capacitor 26 is mounted on the board 21 in a posture in which an axis of the cylindrical component main body 26a stands upright perpendicular to the first surface 21a of the board 21. The capacitor 26 is, for example, an electrolytic capacitor. The capacitor 26 is an example of a “second electronic component”. Note that, the number of capacitors 26 may be one.

### <3. Housing>

Returning to FIG. 1, the housing 10 will be described. The housing 10 is a member that forms an outer periphery of the semiconductor storage device 1. The housing 10 is made of, for example, a metal. The housing 10 has a housing space CS. The board unit 20 is housed in the housing space CS.

The housing 10 has a first end part 10e1 and a second end part 10e2 as end parts of the housing 10 in the longitudinal direction (X direction). The first end part 10e1 is an end part of the housing 10 on the side in the −X direction. The second end part 10e2 is an end part of the housing 10 on the side in the +X direction. In the first embodiment, the second end part 10e2 of the housing 10 has a pair of through holes 10h. The through hole 10h opens in the Z direction. A fastening member FS1 (for example, a screw) for fixing the semiconductor storage device 1 to the host device is inserted through the through hole 10h.

A shape of the housing 10 is, for example, flat rectangular cylinder. The housing 10 has, for example, the first main wall 11, the second main wall 12, a first side wall 13, and a second side wall 14. The first main wall 11, the second main wall 12, the first side wall 13, and the second side wall 14 are walls that define the housing space CS.

The first main wall 11 is positioned on the side in the +Z direction with respect to the board unit 20. The first main wall 11 is a plate portion extending in the X direction and the Y direction. The first main wall 11 has an inner surface 11a facing the housing space CS (refer to FIG. 8). The inner surface 11a is a surface facing in the −Z direction. The inner surface 11a extends in the X direction and the Y direction. A second cover member 50 to be described later is connected to the inner surface 11a of the first main wall 11.

The second main wall 12 is positioned on the side in the −Z direction with respect to the board unit 20. The second main wall 12 is a plate portion extending in the X direction and the Y direction. The first side wall 13 is positioned on the side in the −Y direction with respect to the board unit 20. The first side wall 13 has a plate shape extending in the X direction and the Z direction. The first side wall 13 connects an end part of the first main wall 11 on the side in the −Y direction and an end part of the second main wall 12 on the side in the −Y direction. The second side wall 14 is positioned on the side in the +Y direction with respect to the board unit 20. The second side wall 14 has a plate shape extending in the X direction and the Z direction. The second side wall 14 connects an end part of the first main wall 11 on the side in the +Y direction and an end part of the second main wall 12 on the side in the +Y direction.

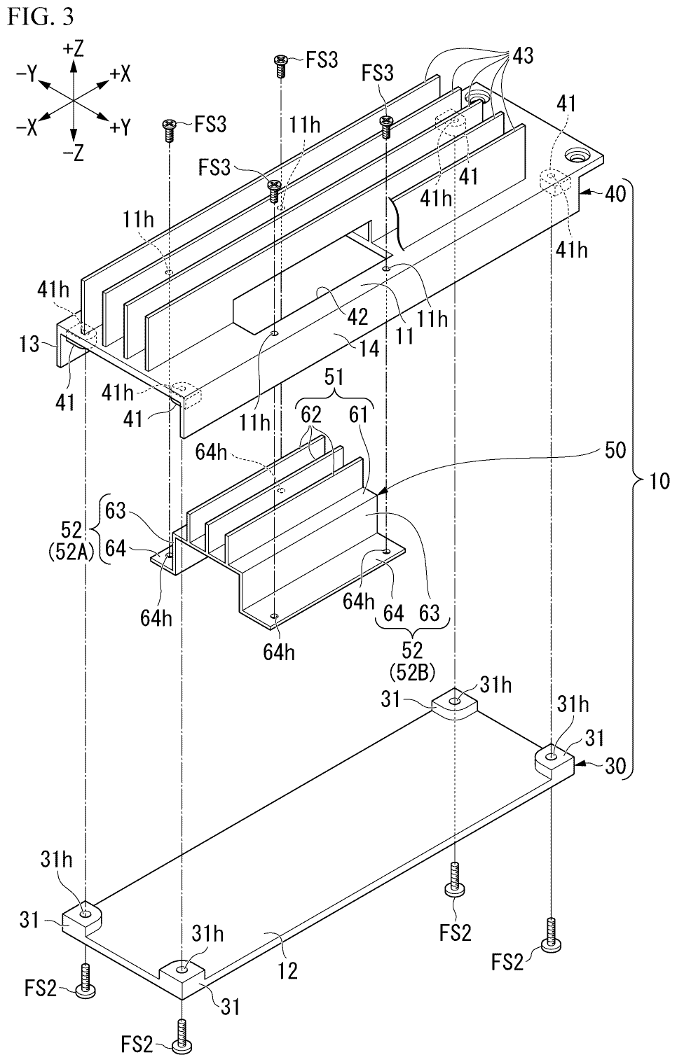

FIG. 3 is an exploded perspective view showing the housing 10. The housing 10 includes, for example, a first cover member 30, a base member 40, and the second cover member 50. In the first embodiment, the housing 10 is formed by combining the first cover member 30, the base member 40, and the second cover member 50.

### <3.1 First Cover Member>

First, the first cover member 30 will be described. The first cover member 30 is a member that includes the second main wall 12. The first cover member 30 is a plate member extending in the X direction and the Y direction. The first cover member 30 has a rectangular shape when viewed from the Z direction. Each of four corners of the first cover member 30 has a support portion 31. The support portion 31 protrudes in the +Z direction from the second main wall 12. The support portion 31 is in contact with the second surface 21b of the board 21 and supports the board 21 from the side in the −Z direction. The support portion 31 has a through hole 31h. The through hole 31h opens in the Z direction. The fastening member FS2 (for example, a screw) to be described later is inserted through the through hole 10h.

### <3.2 Base Member>

Next, the base member 40 will be described. The base member 40 is a member including the first main wall 11, the first side wall 13, and the second side wall 14. The base member 40 is made of a metal (for example, an aluminum alloy). The first main wall 11 is an example of a “first wall”. The base member 40 is an example of a “first member”.

The base member 40 has a rectangular shape when viewed from the Z direction. Each of four corners of the base member 40 has a support portion 41. The support portion 41 protrudes in the −Z direction from the first main wall 11. The support portion 41 is in contact with the first surface 21a of the board 21 and supports the board 21 from the side in the +Z direction. The support portion 41 has a mounting hole 41h. The mounting hole 41h has a female thread and opens in the Z direction. The fastening member FS2 is engaged with the mounting hole 41h. The fastening member FS2 passes through the through hole 31h of the first cover member 30 and the through hole 21h of the board 21. Therefore, the first cover member 30 and the base member 40 are fixed together with the board 21 disposed between the first cover member 30 and the base member 40. Note that, instead of the above-described example, the base member 40 may have a through hole (insertion hole), and the first cover member 30 may have a mounting hole having a female thread.

### (Structure of First Main Wall)

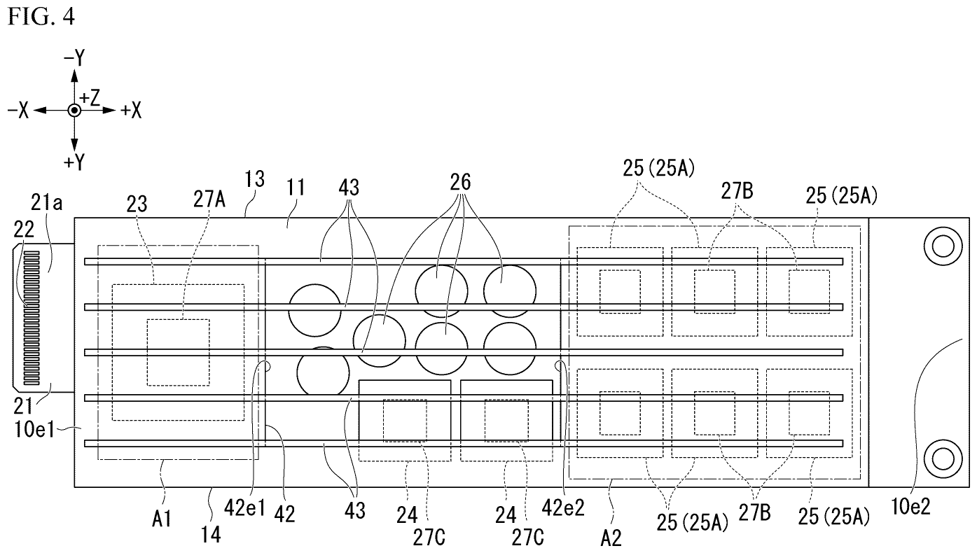

FIG. 4 is a plan view showing the semiconductor storage device 1. Note that, for convenience of explanation, illustration of the second cover member 50 is omitted in FIG. 4. In the first embodiment, the first main wall 11 has a first region A1, a second region A2, and an opening 42.

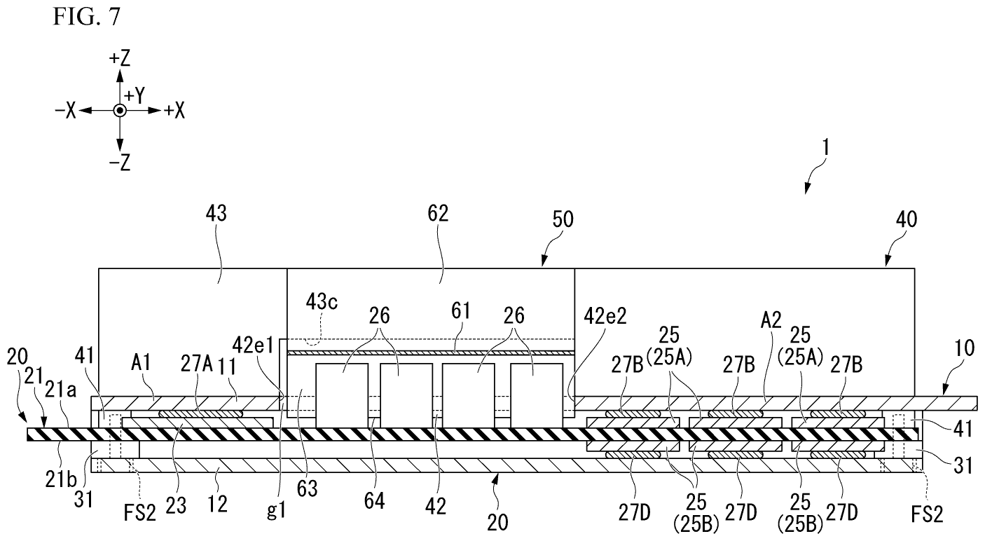

The first region A1 is positioned between the first end part 10e1 of the housing 10 and the opening 42 in the X direction. The first region A1 faces the controller 23 when viewed from the Z direction. The first region A1 is a heat receiving portion to which at least some of heat generated by the controller 23 is transferred. For example, a heat conductive member 27A is provided between the first region A1 and the controller 23 (refer to FIG. 7). The first region A1 is thermally connected to the controller 23 via the heat conductive member 27A. The heat conductive member 27A is, for example, a member having elasticity. The heat conductive member 27A is, for example, a heat conductive sheet.

The second region A2 is positioned between the second end part 10e2 of the housing 10 and the opening 42 in the X direction. The second region A2 faces the plurality of NANDs 25 when viewed from the Z direction. The second region A2 is a heat receiving portion to which at least some of heat generated from the plurality of NANDs 25 is transferred. For example, the heat conductive member 27B is sandwiched between the second region A2 and each of the plurality of NANDs 25 (refer to FIG. 7). The second region A2 is thermally connected to the NANDs 25 via the heat conductive member 27B. The heat conductive member 27B is, for example, a member having elasticity. The heat conductive member 27B is, for example, a heat conductive sheet. The heat conductive member 27B is an example of a “first heat conductive member”.

The opening 42 is provided between the first region A1 and the second region A2 in the X direction. The opening 42 faces the plurality of capacitors 26 when viewed from the Z direction. Since the opening 42 is provided, an interference between the first main wall 11 and with the capacitor 26 serving as a tall electronic component is avoided. In the first embodiment, each capacitor 26 is inserted into the opening 42 (refer to FIG. 7). Each capacitor 26 protrudes further in the +Z direction than the first main wall 11. Also, in the first embodiment, when viewed from the Z direction, at least a part of each of the plurality of DRAMs 24 faces the opening 42.

In the first embodiment, the first main wall 11 has a through hole 11h at a position close to the opening 42 (refer to FIG. 3). The through hole 11h penetrates the first main wall 11 in the Z direction. A fastening member FS3 (for example, a screw) to be described later is inserted through the through hole 11h.

### (First Fin)

In the first embodiment, the base member 40 has one or more (for example, a plurality of) first fins 43. The plurality of first fins 43 are provided on the first main wall 11. Each of the plurality of first fins 43 protrudes in the +Z direction from the first main wall 11. The plurality of first fins 43 are disposed to be aligned in the Y direction. Each of the plurality of first fins 43 extends in the X direction. Each of the plurality of first fins 43 is a plate portion extending in the X direction and the Z direction. Each of the plurality of first fins 43 extends across the opening 42 (to overlap the opening 42) when viewed from the Z direction. Each of the plurality of first fins 43 is provided across the first region A1 and the second region A2 of the first main wall 11. For example, a part of the plurality of first fins 43 are provided in the first region A1 of the first main wall 11. Another part of the plurality of first fins 43 are provided in the second region A2 of the first main wall 11. Each of the plurality of first fins 43 is a heat dissipation portion. The heat dissipation portion dissipates heat from the first region A1 and the second region A2 of the first main wall 11 to the outside of the housing 10.

In the first embodiment, the first fin 43 has a notch 43c positioned in a portion corresponding to the opening 42. The notch 43c is a notch. The notch penetrates the first fin 43 in the Y direction. The notch 43c is provided adjacent to an edge of the first fin 43 on the side in the −Z direction.

The notch 43c faces one or more capacitors 26 when viewed from the Z direction. Since the notch 43c is provided, an interference between the first fin 43 and the capacitor 26 serving as a tall electronic component is avoided. In the first embodiment, each capacitor 26 is inserted into the notch 43c (refer to FIG. 8). Each capacitor 26 protrudes further in the +Z direction than an edge of the first fin 43 on the side in the −Z direction.

### <3.3 Second Cover Member>

Next, the second cover member 50 will be described.

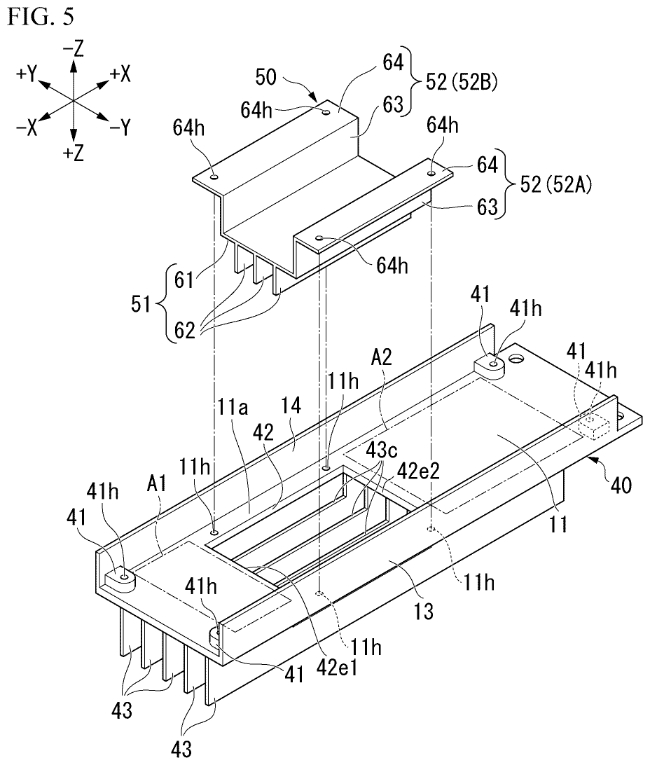

FIG. 5 is a perspective view for explaining the second cover member 50. The second cover member 50 is a member provided to correspond to the opening 42 of the base member 40. The second cover member 50 is made of a metal (for example, an aluminum alloy). The second cover member 50 is an example of a “second member”. The second cover member 50 has, for example, a main body portion 51 and a pair of support portions 52. In the first embodiment, the main body portion 51 and the pair of support portions 52 are integrally formed as a single piece member by extrusion processing.

### <3.3.1 Main Body Portion>

The main body portion 51 is a portion that forms a main portion of the second cover member 50. The main body portion 51 includes, for example, a cover portion 61 and one or more (for example, a plurality of) second fins 62.

### (Cover Portion)

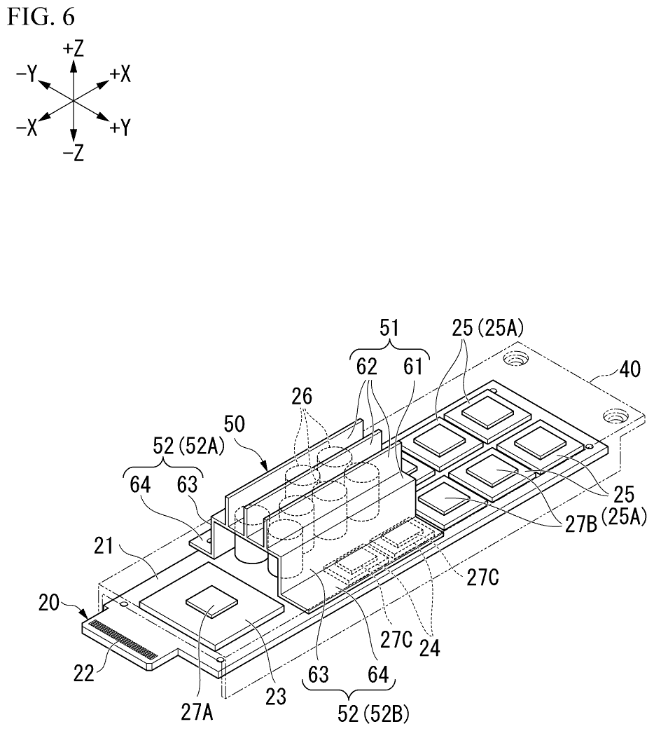

FIG. 6 is another perspective view for explaining the second cover member 50. For convenience of explanation, illustration of the first fins 43 is omitted in FIG. 6. The cover portion 61 is a portion that covers the plurality of capacitors 26 from the side in the +Z direction. The cover portion 61 is disposed at a position further away from the board 21 than the first main wall 11 (refer to FIG. 8). When viewed from the Z direction, the cover portion 61 faces the plurality of capacitors 26. The cover portion 61 covers the plurality of capacitors 26 from a side opposite to the board 21. In the first embodiment, the cover portion 61 is a plate portion extending in the X direction and the Y direction. The cover portion 61 may be referred to as a “second wall”. A length W2 of the cover portion 61 in the Y direction is smaller than a length W1 of the opening 42 in the Y direction.

FIG. 7 is a cross-sectional view taken along line F7-F7 of the semiconductor storage device 1 shown in FIG. 1. In the first embodiment, the cover portion 61 is disposed inside the notch 43c of the first fin 43. The cover portion 61 extends in the Y direction through the notches 43c of the plurality of first fins 43 (refer to FIG. 8).

### (Second Fin)

FIG. 8 is a cross-sectional view taken along line F8-F8 of the semiconductor storage device 1 shown in FIG. 1. The plurality of second fins 62 are provided on the cover portion 61. Each of the plurality of second fins 62 protrudes in the +Z direction from the cover portion 61. Each of the plurality of second fins 62 protrudes from the cover portion 61 toward a side opposite to the capacitor 26. When viewed from the Z direction, each of the plurality of second fins 62 overlaps the capacitor 26. The second fin 62 is an example of a “protrusion”.

The plurality of second fins 62 are disposed to be aligned in the Y direction. Each of the plurality of second fins 62 extends in the X direction. Each of the plurality of second fins 62 is a plate portion extending in the X direction and the Z direction. Each of the plurality of second fins 62 extends, for example, over the entire length of the cover portion 61 in the X direction (refer to FIG. 7). Each of the plurality of second fins 62 is a heat dissipation portion. The heat dissipation portion dissipates heat from the cover portion 61 to the outside of the housing 10.

In the first embodiment, the plurality of second fins 62 are disposed alternately with the plurality of first fins 43 in the Y direction. That is, each of the plurality of second fins 62 is disposed between two adjacent first fins 43 in the Y direction. The first fin 43 is provided to form a gap S between the first fin 43 and the second fin 62. Air can flow in the gap S.

In the first embodiment, the second fin 62 extends further in the +Z direction than an edge on the side in the +Z direction of the notch 43c of the first fin 43. For example, a length L2 of the second fin 62 in the Z direction is larger than or equal to half a length L1 of the first fin 43 in the Z direction. For example, regarding a position in the Z direction, an end 62e of the second fin 62 on the side in the +Z direction is disposed at the same position as an end 43e of the first fin 43 on the side in the +Z direction.

### <3.3.2 Support Portion>

Each of the pair of support portions 52 is connected to the base member 40 and supports the main body portion 51. The support portion 52 is adjacent to the main body portion 51 in the Y direction. The support portion 52 has, for example, an upright portion 63 and an attachment portion 64.

### (Upright Portion)

The upright portion 63 is an extension portion that extends between the cover portion 61 and the attachment portion 64. For example, the upright portion 63 extends in the Z direction through the opening 42. The upright portion 63 is adjacent to the plurality of capacitors 26 in the Y direction. An end part of the upright portion 63 on the side in the +Z direction is connected to the cover portion 61 at a position on the side in the +Z direction of the first main wall 11. An end part of the upright portion 63 on the side in the −Z direction is connected to the attachment portion 64 at a position on the side in the −Z direction of the first main wall 11. In the first embodiment, the upright portion 63 is a plate portion extending in the X direction and the Z direction. The upright portion 63 extends, for example, over the entire length of the cover portion 61 in the X direction. The upright portion 63 may be referred to as a “third wall”.

### (Attachment Portion)

The attachment portion 64 is a portion that is attached to the base member 40. The attachment portion 64 extends in the Y direction from an end part of the upright portion 63 on the side in the −Z direction toward the outside of the housing 10. The attachment portion 64 faces the inner surface 11a of the first main wall 11 from the side in the −Z direction. The attachment portion 64 is a plate portion extending in the X direction and the Y direction. In the first embodiment, the attachment portion 64 is fixed to the first main wall 11 and supported by the first main wall 11. The attachment portion 64 extends, for example, over the entire length of the cover portion 61 in the X direction.

In the first embodiment, the attachment portion 64 has an attachment hole 64h (refer to FIG. 3). The attachment hole 64h has a female thread. The attachment hole 64h opens in the Z direction. The fastening member FS3 inserted through the through hole 11h of the first main wall 11 is engaged with the attachment hole 64h. Therefore, the attachment portion 64 is fixed to the first main wall 11, and the base member 40 and the second cover member 50 are integrated together.

Note that, instead of the above-described configuration, the attachment portion 64 may have a through hole (insertion hole), and the first main wall 11 may have an attachment hole with a female thread. Also, a fixing structure between the attachment portion 64 and the first main wall 11 is not limited to a configuration using a fastening member. For example, the fixing structure between the attachment portion 64 and the first main wall 11 may be a method using an adhesive sheet or an adhesive, a method using metal bonding, or the like.

As shown in FIG. 8, the second cover member 50 has the pair of support portions 52, that is, a first support portion 52A and a second support portion 52B. The first support portion 52A is positioned on the side in the −Y direction with respect to the cover portion 61. The second support portion 52B is positioned on the side in the +Y direction with respect to the cover portion 61.

In the first embodiment, the upright portion 63 of the first support portion 52A is connected to an end part of the cover portion 61 in the −Y direction. The upright portion 63 of the second support portion 52B is connected to an end part of the cover portion 61 in the +Y direction. In the first embodiment, the upright portion 63 of the first support portion 52A and the upright portion 63 of the second support portion 52B have the same shape.

On the other hand, the attachment portion 64 of the first support portion 52A and the attachment portion 64 of the second support portion 52B have different shapes. For example, a length L4 in the Y direction of the attachment portion 64 of the second support portion 52B is larger than a length L3 in the Y direction of the attachment portion 64 of the first support portion 52A.

In the first embodiment, the attachment portion 64 of the second support portion 52B faces the DRAM 24 when viewed from the Z direction. For example, when viewed from the Z direction, the attachment portion 64 of the second support portion 52B faces the plurality of DRAMs 24 (refer to FIG. 6). A heat conductive member 27C is sandwiched between the attachment portion 64 of the second support portion 52B and each of the plurality of DRAMs 24. The attachment portion 64 of the second support portion 52B is thermally connected to the DRAM 24 via the heat conductive member 27C. The heat conductive member 27C is, for example, a member having elasticity. The heat conductive member 27C is, for example, a heat conductive sheet. The attachment portion 64 of the second support portion 52B is an example of a “heat receiving portion”. The heat conductive member 27C is an example of a “second heat conductive member”.

In the first embodiment, at least a part of the DRAMs 24 faces the opening 42 when viewed from the Z direction. At least a part of the attachment portion 64 of the second support portion 52B is thermally connected to the DRAMs 24 via the heat conductive member 27C at a position overlapping the opening 42 when viewed from the Z direction.

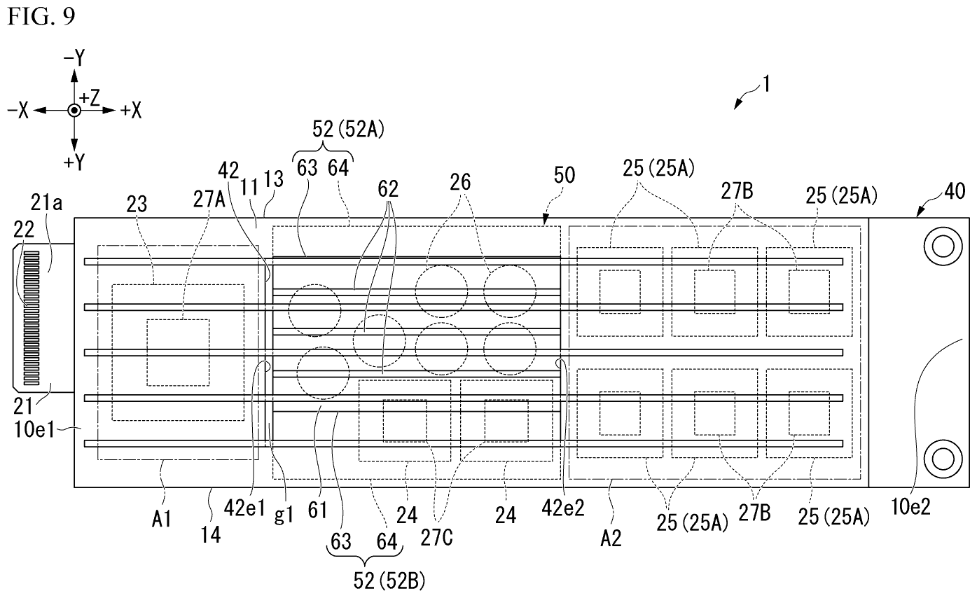

FIG. 9 is a plan view showing the semiconductor storage device 1. In the first embodiment, the opening 42 has a pair of ends in the X direction, that is, a first end 42e1 and a second end 42e2. The first end 42a is an end on the side in the −X direction. The first end 42a is adjacent to the first region A1 of the first main wall 11. The first end 42a extends in the Y direction. The second end 42b is an end on the side in the −X direction. The second end 42b is adjacent to the second region A2 of the first main wall 11. The second end 42b extends in the Y direction.

In the first embodiment, when viewed from the Z direction, the second cover member 50 is provided to form a gap g1 between the second cover member 50 and the first end 42a of the opening 42. At a boundary portion between the first end 42a of the opening 42 and the second cover member 50, the first main wall 11 and the second cover member 50 are not in contact with each other. When the gap g1 is present, transfer of heat from the first region A1 of the first main wall 11 to the second cover member 50 is suppressed compared to a case in which the gap g1 is not present.

On the other hand, when viewed from the Z direction, a gap may not be formed between the second cover member 50 and the second end 42b of the opening 42. For example, at a boundary portion between the second end 42b of the opening 42 and the second cover member 50, the first main wall 11 and the second cover member 50 are in contact with each other. Note that, the second cover member 50 may be provided to form a gap similar to the gap g1 between the second cover member 50 and the second end 42b of the opening 42.

### <4. Function>

(From Perspective of Suppressing Contact from Outside)

When the second cover member 50 is attached to the base member 40, the capacitor 26 is covered from the side in the +Z direction by the cover portion 61 of the second cover member 50. Therefore, the capacitor 26 is not significantly exposed to the outside of the housing 10. Therefore, the capacitor 26 is less likely to be contacted from the outside, and a problem in the capacitor 26 or the board 21 is less likely to occur.

### (From Perspective of Heat Dissipation)

Some of heat generated from the DRAM 24 is transferred to the attachment portion 64 of the second cover member 50 via the heat conductive member 27C. The heat transferred to the attachment portion 64 of the second cover member 50 is transferred to the cover portion 61 and the plurality of second fins 62 via the upright portion 63. The heat transferred to the cover portion 61 and the plurality of second fins 62 is dissipated from the cover portion 61 and the plurality of second fins 62 to the outside of the housing 10.

### <5. Advantages>

As a comparative example, a semiconductor storage device not including the second cover member 50 will be considered. In such a configuration of the comparative example, for example, if the opening 42 is provided to avoid interference with the capacitor 26, a heat dissipation area of the housing 10 decreases. Therefore, improvement in heat dissipation of the semiconductor storage device may be difficult to achieve. Also, if the capacitor 26 is exposed to the outside of the housing 10 through the opening 42, there is a possibility that a problem occurs in the capacitor 26 or the board 21 due to contact through the opening 42.

On the other hand, the semiconductor storage device 1 of the first embodiment has the housing 10, the board 21, the NAND 25, and the capacitor 26. The capacitor 26 has a larger height from the first surface 21a of the board 21 compared to the NAND 25. The housing 10 includes the base member 40 and the second cover member 50. When viewed from the Z direction, the base member 40 has the first main wall 11 facing the NAND 25 and the opening 42 facing the capacitor 26. The second cover member 50 has the main body portion 51 and the support portion 52. The main body portion 51 covers the capacitor 26 at a position further away from the board 21 than the first main wall 11. The main body portion 51 includes one or more second fins 62. The support portion 52 is connected to the base member 40 to support the main body portion 51.

According to such a configuration, the second cover member 50 covers the capacitor 26 and has one or more protrusions (for example, the second fins 62), and a heat dissipation area increases due to a presence of the second cover member 50. Therefore, improvement in heat dissipation of the semiconductor storage device 1 is achieved. Also, since the second cover member 50 that covers the capacitor 26 is provided, a problem caused in the capacitor 26 or the board 21 due to contact through the opening 42 is suppressed.

In the first embodiment, the protrusions described above extend in the X direction. When such protrusions are provided, it is easy to achieve further improvement in heat dissipation of the semiconductor storage device 1.

In the first embodiment, the main body portion 51 includes the cover portion 61. The cover portion 61 covers the capacitor 26 at a position further away from the board 21 than the first main wall 11. One or more protrusions described above are one or more second fins 62 protruding from the cover portion 61 to a side opposite to the capacitor 26. According to such a configuration, since the second fins 62 is present, it is easy to achieve further improvement in heat dissipation of the semiconductor storage device 1.

In the first embodiment, the base member 40 has the plurality of first fins 43 provided on the first main wall 11. One or more second fins 62 described above include the second fin 62 disposed between the plurality of first fins 43 in the Y direction. According to such a configuration, a size or shape of the second fins 62 is less likely to be restricted by the first fins 43. Therefore, a degree of freedom in size and shape of the second fins 62 increases. Therefore, achieving further improvement in heat dissipation of the semiconductor storage device 1 is facilitated.

In the first embodiment, the length L2 in the Z direction of the second fin 62 is larger than or equal to half the length L1 in the Z direction of one first fin 43 included in the plurality of first fins 43. According to such a configuration, since such a large second fin 62 is provided, achieving further improvement in heat dissipation of the semiconductor storage device 1 is facilitated.

In the first embodiment, the support portion 52 includes the upright portion 63. The upright portion 63 passes through the opening 42 and is connected to the main body portion 51. According to such a configuration, the support portion 52 can extend through the opening 42, spanning the outside and inside of the base member 40. Therefore, it is easy for a larger amount of heat to escape from the inside of the housing 10 to the outside of the housing 10. Therefore, achieving further improvement in heat dissipation of the semiconductor storage device 1 is facilitated.

In the first embodiment, the first main wall 11 is thermally connected to the NAND 25 via the heat conductive member 27B. The second support portion 52B includes a heat receiving portion (attachment portion 64) that is connected to the upright portion 63 and faces the DRAM 24 when viewed from the Z direction. The heat receiving portion described above is thermally connected to the DRAM 24 via the heat conductive member 27C. According to such a configuration, heat from the DRAM 24 can be made to escape to the outside of the housing 10 through the second cover member 50. Therefore, achieving further improvement in heat dissipation of the semiconductor storage device 1 is facilitated.

In the first embodiment, at least a part of the DRAMs 24 face the opening 42 when viewed from the Z direction. At least a part of the above-described heat receiving portion (attachment portion 64) is thermally connected to the DRAM 24 via the heat conductive member 27C at a position overlapping the opening 42 when viewed from the Z direction. According to such a configuration, even if the opening 42 provided to avoid interference with the capacitor 26 overlaps the DRAM 24 in the Z direction, heat generated from the DRAM 24 is made to escape through the second cover member 50. Therefore, achieving further improvement in heat dissipation of the semiconductor storage device 1 is facilitated.

In the first embodiment, the heat receiving portion described above is attached to the first main wall 11 inside the housing 10. According to such a configuration, a heat receiving portion receiving heat from the DRAM 24 can be formed by the attachment portion for attaching the support portion 52 to the housing 10. Therefore, reduction in size of the semiconductor storage device 1 is achieved compared to a case in which the attachment portion for attaching the support portion 52 to the housing 10 and the heat receiving portion for receiving heat from the DRAM 24 are formed separately.

In the first embodiment, the semiconductor storage device 1 includes the controller 23 whose temperature during operation becomes higher than that of the NAND 25. The first main wall 11 includes the first region A1 facing the controller 23 and the second region A2 facing the NAND 24 when viewed from the Z direction. The opening 42 is provided between the first region A1 and the second region A2 in the first main wall 11. According to such a configuration, due to the presence of the opening 42, heat transferred from the controller 23 to the first region A1 is less likely to transfer from the first region A1 to the second region A2. Therefore, an increase in temperature of the NAND 25 caused by the heat transferred from the controller to the first region A1 is suppressed. Therefore, a problem related to the NAND 25 is less likely to occur.

In the first embodiment, the opening 42 has the first end 42e1 adjacent to the first region A1. When viewed from the Z direction, the first end 42e1 of the opening 42 is provided with the gap g1 between the first end 42e1 and the cover portion 61. According to such a configuration, heat transferred from the controller 23 to the first region A1 is less likely to transfer from the first region A1 to the second region A2 due to the presence of the gap g1. Therefore, an increase in temperature of the NAND 25 caused by the heat transferred from the controller to the first region A1 is suppressed. Therefore, a problem related to the NAND 25 is even less likely to occur.

### <6. Modified Examples>

Next, modified examples of the first embodiment will be described. In each modified example, configurations other than those described below are the same as the configurations of the first embodiment.

### <6.1 First Modified Example>

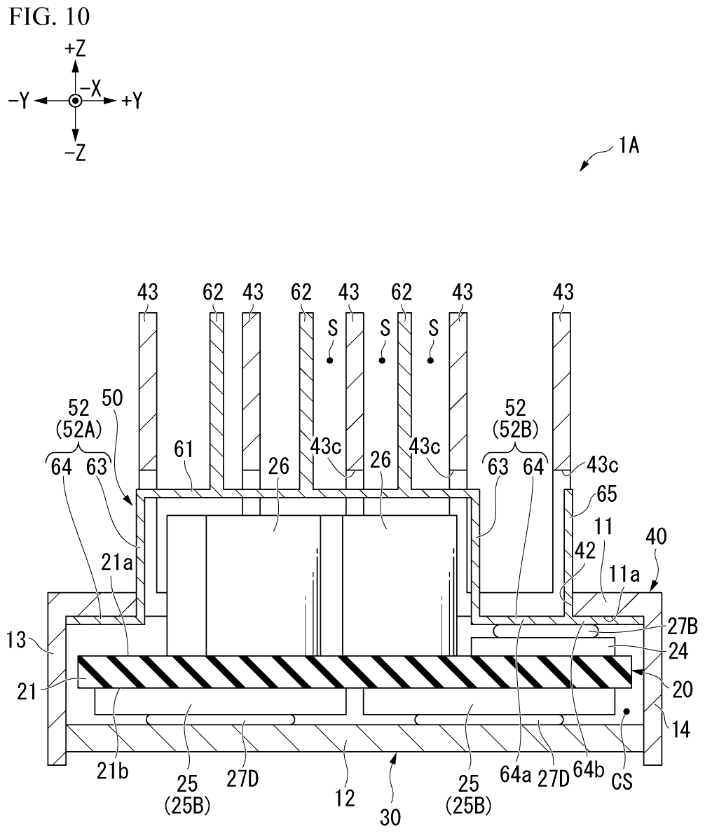

FIG. 10 is a cross-sectional view showing a semiconductor storage device 1A of a first modified example. In the first modified example, the attachment portion 64 of the support portion 52B of the second cover member 50 has a first portion 64a and a second portion 64b. When viewed from the Z direction, the first portion 64a faces the opening 42. The first portion 64a is exposed to the outside of the housing 10 through the opening 42. On the other hand, the second portion 64b is positioned on the side in the +Y direction with respect to the first portion 64a. When viewed from the Z direction, the second portion 64b faces the first main wall 11 of the housing 10. The second portion 64b is not exposed to the outside of the housing 10 through the opening 42. The second portion 64b is disposed on the side in the −Z direction of the first main wall 11 of the housing 10. The second portion 64b is fixed to the first main wall 11 of the housing 10.

In the first embodiment, the second cover member 50 has a third fin 65 in addition to the plurality of second fins 62. The third fin 65 is provided on the first portion 64a of the attachment portion 64 of the second cover member 50. The third fin 65 does not overlap the capacitor 26 when viewed from the Z direction. The third fin 65 extends in the +Z direction from the first portion 64a of the attachment portion 64 of the second cover member 50. A length of the third fin 65 in the Z direction is, for example, the same as a length of the upright portion 63 in the Z direction.

The third fin 65 extends, for example, over the entire length of the cover portion 61 in the X direction. The third fin 65 is a plate portion extending in the X direction and the Z direction. When viewed from the Z direction, the third fin 65 at least partially overlaps one of the first fins 43. At least a part of the third fin 65 is disposed in the notch 43c of one of the first fins 43.

According to such a configuration, the third fin 65 is provided by utilizing a region that does not overlap the capacitor 26 when viewed from the Z direction. When the third fin 65 is provided, a heat dissipation area of the housing 10 can be further increased without an increase in size of the semiconductor storage device 1A. Therefore, achieving further improvement in heat dissipation of the semiconductor storage device 1A is facilitated.

### <6.2 Second Modified Example>

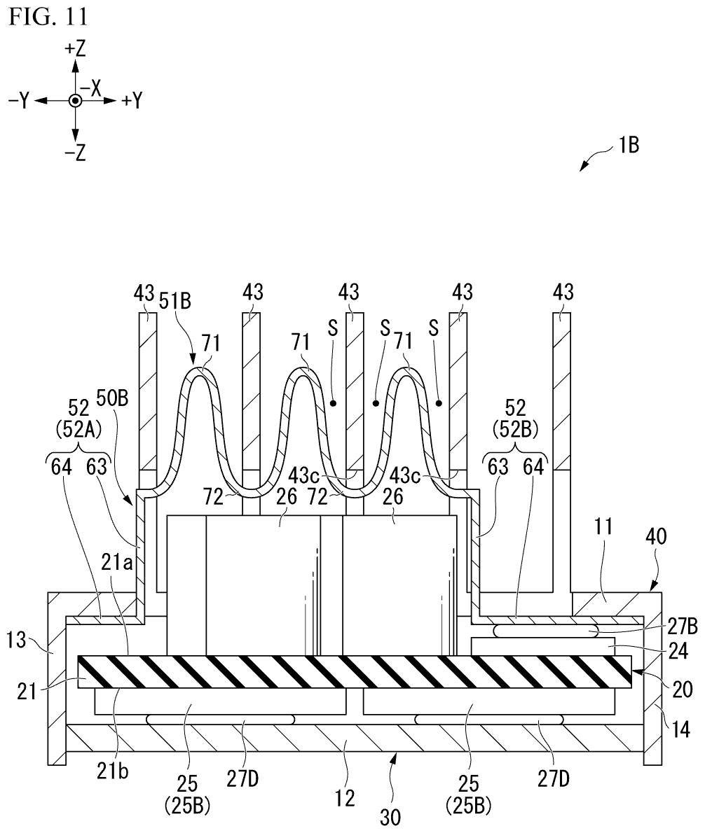

FIG. 11 is a cross-sectional view showing a semiconductor storage device 1B of a second modified example. In the second modified example, the semiconductor storage device 1B has a second cover member 50B instead of the second cover member 50. The second cover member 50B has a main body portion 51B and the pair of support portions 52.

The main body portion 51B has, for example, a wave shape when viewed from the X direction. The main body portion 51B covers the plurality of capacitors 26 at a position further away from the board 21 than the first main wall 11 and has one or more (for example, a plurality of) protrusions 71 protruding toward a side opposite to the capacitors 26. For example, the main body portion 51B has the plurality of protrusions 71 protruding toward a side opposite to the capacitors 26, and a recess 72 disposed between two adjacent protrusions 71 in the Y direction and recessed toward the side in the −Z direction. The protrusions 71 and the recesses 72 are repeated alternately in the Y direction so that the main body portion 51B is formed in a wave shape when viewed from the X direction. In the second modified example, the main body portion 51B including the protrusions 71 and the recesses 72 and the pair of support portions 52 are integrally formed as a single piece member using press working.

In the second modified example, the protrusion 71 extends further in the +Z direction than the edge on the side in the +Z direction of the notch 43c of the first fin 43. The recess 72 is disposed in the notch 43c of the first fin 43. The protrusion 71 and the recess 72 extend in the X direction. The protrusion 71 and the recess 72 extend, for example, over the entire length of the main body portion 51B in the X direction. The main body portion 51B is a heat dissipation portion. The heat dissipation portion dissipates heat to the outside of the housing 10.

In the second modified example, the plurality of protrusions 71 are disposed to be aligned in the Y direction. For example, the plurality of protrusions 71 are disposed alternately with the plurality of first fins 43 in the Y direction. That is, each of the protrusions 71 is disposed between two adjacent first fins 43 in the Y direction. The first fin 43 is provided with a gap S between the first fin 43 and the protrusion 71, allowing air to flow therethrough.

According to such a configuration, since the main body portion 51B has the protrusions 71, a heat dissipation area of the main body portion 51B can be increased compared to when the main body portion 51B is a flat plate portion. Therefore, achieving further improvement in heat dissipation of the semiconductor storage device 1B is facilitated.

### <6.3 Third Modified Example>

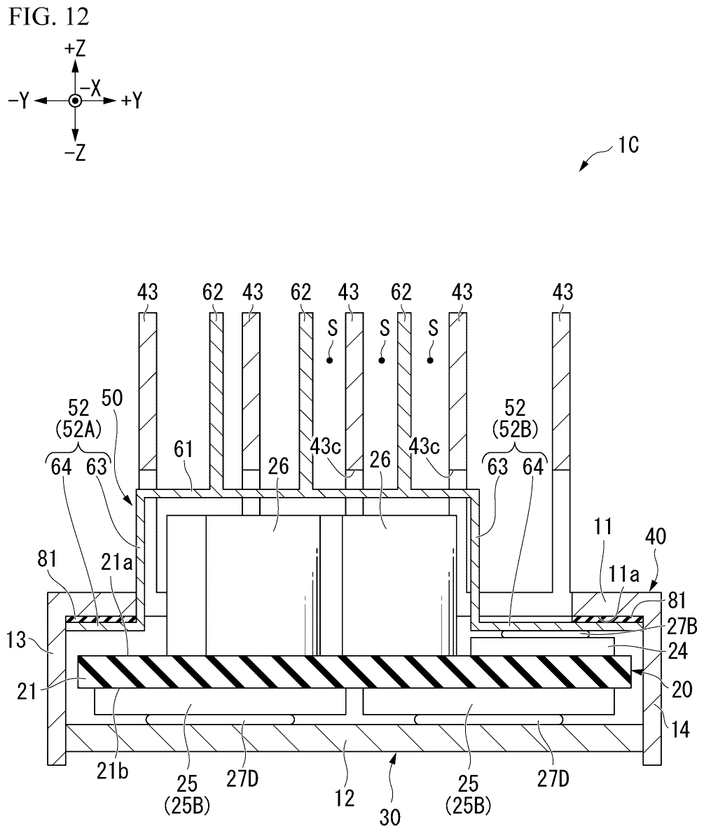

FIG. 12 is a cross-sectional view showing a semiconductor storage device 1C of a third modified example. In the third modified example, a heat insulating member 81 is provided between the attachment portion 64 and the inner surface 11a of the first main wall 11. For example, the heat insulating member 81 is provided between the attachment portion 64 of the first support portion 52A and the inner surface 11a of the first main wall 11. The heat insulating member 81 is provided between the attachment portion 64 of the second support portion 52B and the inner surface 11a of the first main wall 11. The heat insulating member 81 is formed, for example, of a material that is less conductive to heat compared to the first main wall 11. The heat insulating member 81 is, for example, a member having elasticity. The heat insulating member 81 has, for example, a sheet shape extending in the X direction and the Y direction.

According to such a configuration, the heat insulating member 81 is provided. Therefore, heat transfer between the second cover member 50 and the first main wall 11 is suppressed. Therefore, heat transferred from the DRAM 24 to the second cover member 50 is less likely to transfer to the NAND 25 through the first main wall 11. Therefore, an increase in temperature of the NAND 25 is further suppressed. Therefore, a problem related to the NAND 25 is even less likely to occur.

### <6.4 Fourth Modified Example>

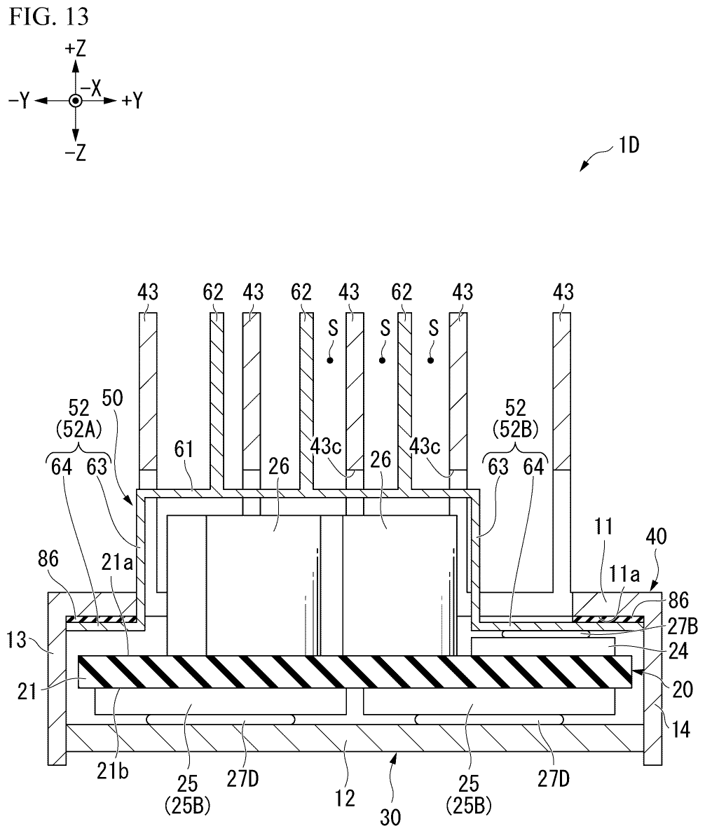

FIG. 13 is a cross-sectional view showing a semiconductor storage device 1D of a fourth modified example. In the fourth modified example, a heat conductive member 86 is provided between the attachment portion 64 and the first main wall 11. For example, the heat conductive member 86 is provided between the attachment portion 64 of the first support portion 52A and the inner surface 11a of the first main wall 11. The heat conductive member 86 is provided between the attachment portion 64 of the second support portion 52B and the inner surface 11a of the first main wall 11. The heat conductive member 86 is, for example, a member having elasticity. The heat conductive member 86 has, for example, a sheet shape extending in the X direction and the Y direction. The heat conductive member 86 is an example of a “third heat conductive member”.

According to such a configuration, the heat conductive member 86 is provided. Therefore, heat is easily transferred between the second cover member 50 and the first main wall 11. Therefore, one of temperatures of the second cover member 50 and the first main wall 11 becoming locally higher than the other can be suppressed. According to such a configuration, it is possible to further suppress a problem related to the semiconductor storage device 1 caused by an increase in temperature.

### Second Embodiment

Next, a semiconductor storage device 1E of a second embodiment will be described. The second embodiment is different from the first embodiment in that a hole 96 is provided in a second cover member 50E. A capacitor 26 is inserted into hole 96. Note that, configurations other than those described below are the same as the configurations of the first embodiment.

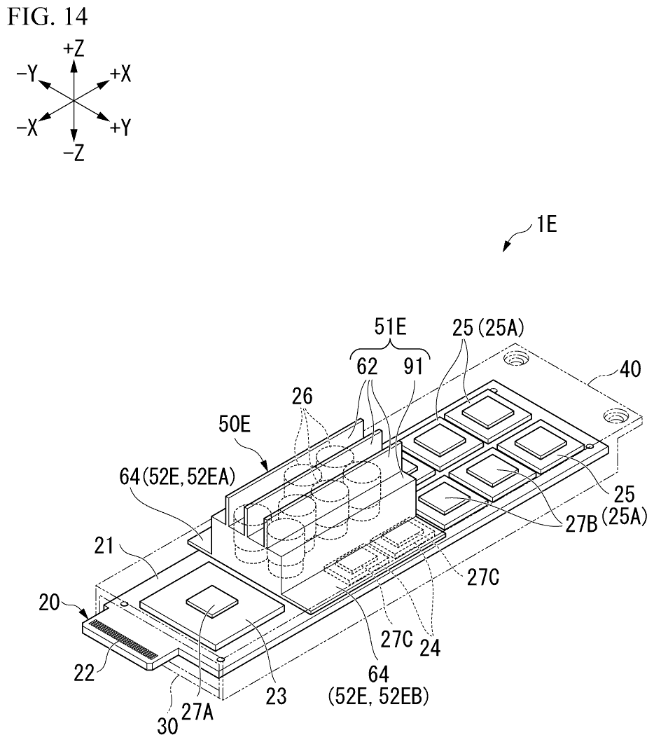

FIG. 14 is a perspective view for explaining the second cover member 50E of the second embodiment. For convenience of explanation, illustration of a first fin 43 is omitted in FIG. 14. In the second embodiment, a housing 10 has the second cover member 50E instead of the second cover member 50 of the first embodiment. The second cover member 50E has a main body portion 51E and a pair of support portions 52E provided separately on both sides of the main body portion 51E in the Y direction.

### (Main Body Portion)

The main body portion 51E has one or more (for example, a plurality of) second fins 62. The second fins 62 cover a plurality of capacitors 26 at a position further away from a board 21 than a first main wall 11, and protrude toward a side opposite to the capacitors 26. The main body portion 51E includes, for example, a base portion 91 and one or more (for example, the plurality of) second fins 62.

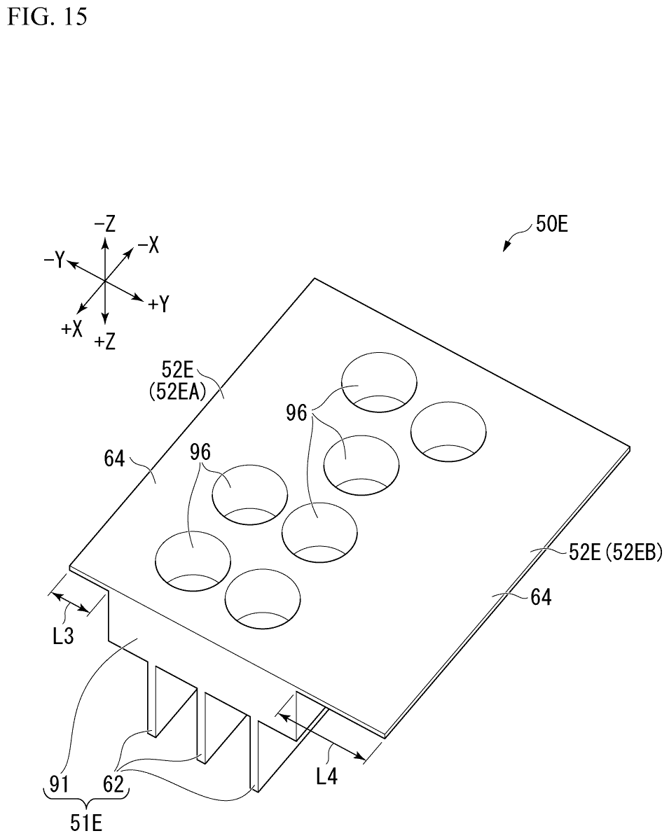

FIG. 15 is a perspective view showing the second cover member 50E of the second embodiment. In the second embodiment, the base portion 91 has a solid rectangular parallelepiped shape. A plurality of holes 96 are formed in the base portion 91. The plurality of holes 96 are open in the −Z direction. When viewed from the Z direction, the plurality of holes 96 are provided at positions in one-to-one correspondence with the plurality of capacitors 26. A diameter of the hole 96 is slightly larger than a diameter of a component main body 26a of the capacitor 26. The component main body 26a of the capacitor 26 is inserted into each hole 96 (refer to FIG. 14). Note that, the hole 96 is not limited to a cylindrical hole, and may also be a prismatic hole or an elliptical hole.

A part of the base portion 91 is disposed at a position further away from the board 21 than the first main wall 11 with the plurality of capacitors 26 housed in the plurality of holes 96 (refer to FIG. 14). The base portion 91 faces the plurality of capacitors 26 when viewed from the Z direction. The base portion 91 covers the plurality of capacitors 26, which are individually housed in the plurality of holes 96, from the side in the +Z direction.

### (Support Portion)

Each of the pair of supports 52E has an attachment portion 64. The attachment portion 64 extends in the Y direction from an end part of the base portion 91 on the side in the −Z direction. In the second embodiment, the pair of support portions 52E includes a first support portion 52EA and a second support portion 52EB. The first support portion 52EA is positioned on the side in the −Y direction with respect to the base portion 91. The second support portion 52EB is positioned on the side in the +Y direction with respect to the base portion 91. The attachment portion 64 of the first support portion 52EA and the attachment portion 64 of the second support portion 52EB have different shapes. For example, a length L4 in the Y direction of the attachment portion 64 of the second support portion 52EB is larger than a length L3 in the Y direction of the attachment portion 64 of the first support portion 52EA.

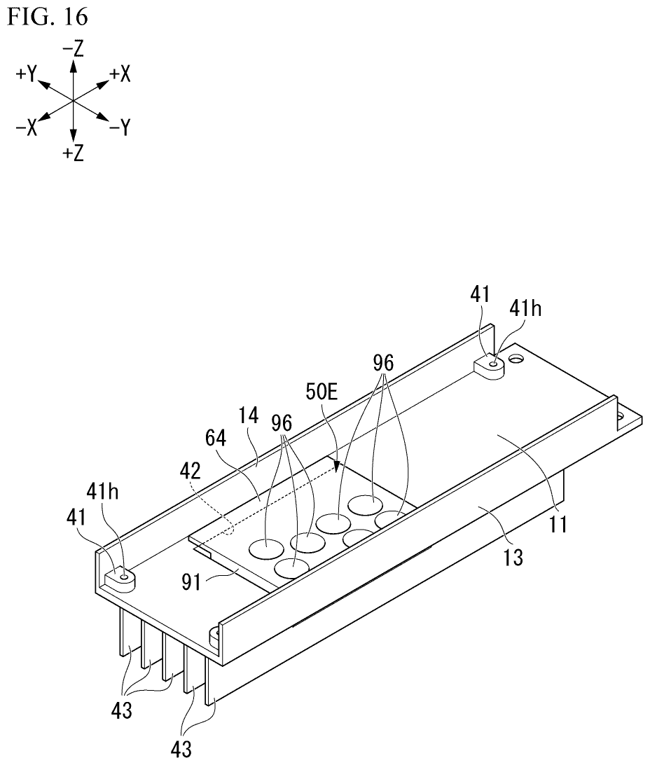

FIG. 16 is another perspective view showing the second cover member 50E of the second embodiment. The attachment portion 64 of the support portion 52E faces an inner surface 11a of the first main wall 11 from the side in the −Z direction. In the second embodiment, the attachment portion 64 is fixed to the first main wall 11 and supported by the first main wall 11. Also, the attachment portion 64 of the second support portion 52EB faces the plurality of DRAMs 24 similarly to the attachment portion 64 of the second support portion 52B of the first embodiment (refer to FIG. 14). The attachment portion 64 of the second support portion 52EB is thermally connected to the DRAMs 24 via a heat conductive member 27C. The attachment portion 64 of the second support portion 52EB is an example of a “heat receiving portion”.

According to such a configuration, as in the first embodiment, improvement in heat dissipation of the semiconductor storage device 1E is achieved. Also, in the second embodiment, the second cover member 50E has the hole 96 into which the capacitor 26 is inserted. When such a hole 96 is provided, falling over or falling off of the capacitor 26 due to vibrations, impacts, or the like are suppressed by the second cover member 50E. Therefore, reliability of the semiconductor storage device 1E is further improved.

### Third Embodiment

Next, a semiconductor storage device 1F of a third embodiment will be described. The third embodiment is different from the first embodiment in that an attachment portion 64 of a second support portion 52B of a second cover member 50F extends further in the X direction than a main body portion 51. Note that, configurations other than those described below are the same as the configurations of the first embodiment.

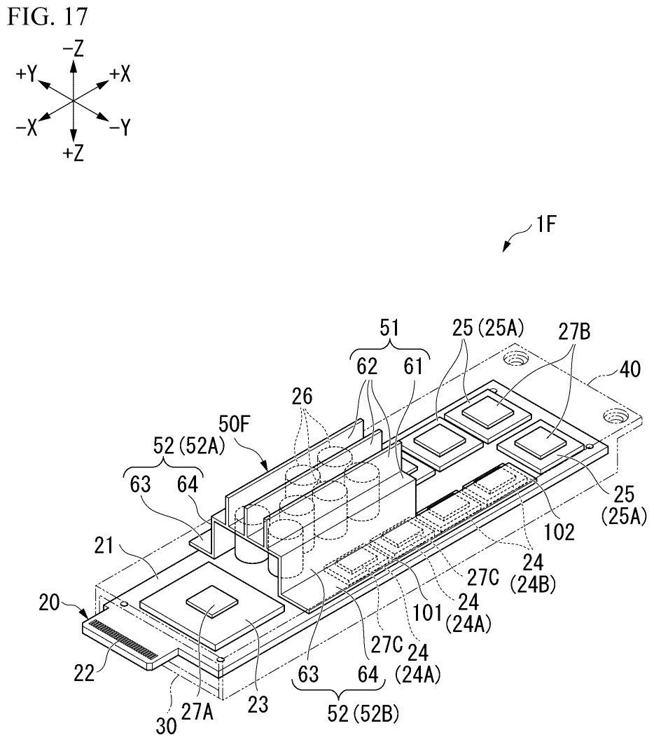

FIG. 17 is a perspective view for explaining the second cover member 50F of the third embodiment. For convenience of explanation, illustration of a first fin 43 is omitted in FIG. 17. In the third embodiment, a board unit 20 has four DRAMs 24. The four DRAMs 24 include, for example, two DRAMs 24A and two DRAMs 24B.

The DRAM 24A is disposed at a position adjacent to the main body portion 51 of the second cover member 50F in the Y direction. On the other hand, the DRAM 24B is disposed on the side in the +X direction of the main body portion 51 of the second cover member 50F in the X direction. The DRAM 24B is disposed at a position not adjacent to the main body portion 51 of the second cover member 50F in the Y direction. Each of the DRAM 24A and the DRAM 24B is an example of a “third electronic component”. Note that, the DRAM 24B may be referred to as a “fifth electronic component”when it is distinguished from the DRAM 24A.

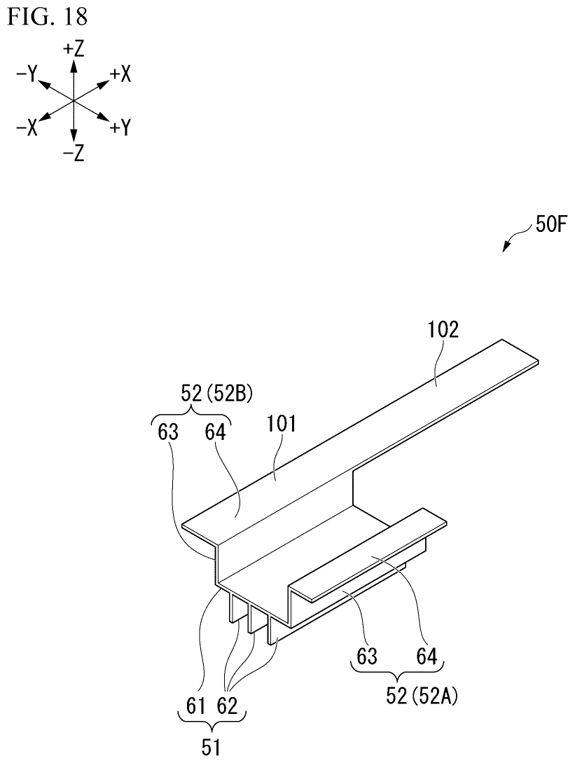

FIG. 18 is a perspective view showing the second cover member 50F of the third embodiment. In the third embodiment, the attachment portion 64 (heat receiving portion) of the second support portion 52B has a first portion 101 and a second portion 102. The first portion 101 is adjacent to the main body portion 51 of the second cover member 50F in the Y direction. On the other hand, the second portion 102 extends in the +X direction from the first portion 101. The second portion 102 is an extension portion that extends further in the X direction than the main body portion 51. That is, the second portion 102 extends further in the +X direction than an edge of the main body portion 51 on the side in the +X direction.

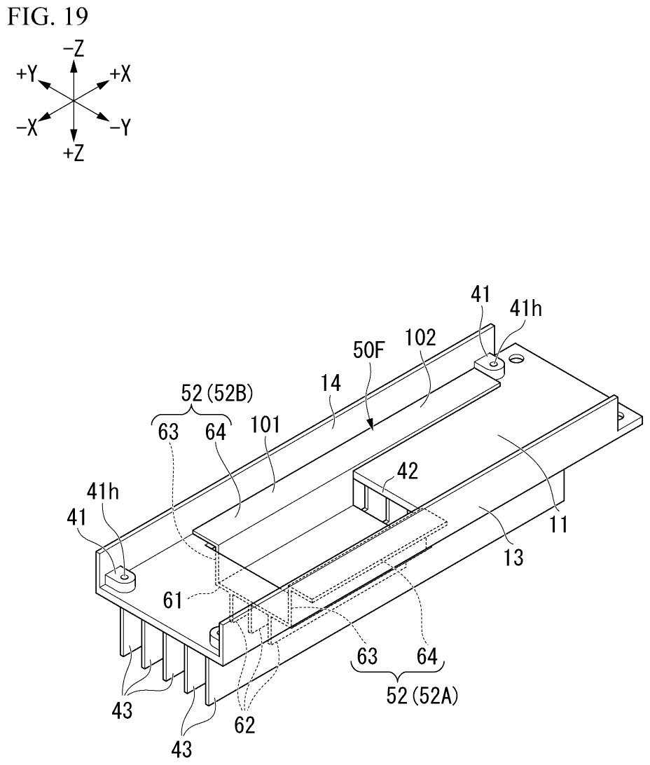

FIG. 19 is another perspective view showing the second cover member 50F of the third embodiment. The attachment portion 64 of the first support portion 52A and the attachment portion 64 of the second support portion 52B face an inner surface 11a of a first main wall 11 from the side in the −Z direction. In the third embodiment, the attachment portion 64 is fixed to the first main wall 11 and supported by the first main wall 11.

The first portion 101 of the attachment portion 64 of the second support portion 52B faces the two DRAMs 24A (refer to FIG. 17). The first portion 101 of the attachment portion 64 of the second support portion 52B is thermally connected to the DRAMs 24A via a heat conductive member 27C. On the other hand, the second portion 102 of the attachment portion 64 of the second support portion 52B faces the two DRAMs 24B (refer to FIG. 17). The second portion 102 of the attachment portion 64 of the second support portion 52B is thermally connected to the DRAMs 24B via the heat conductive member 27C. Note that, an electronic component to which the first portion 101 of the attachment portion 64 of the second support portion 52B is thermally connected and an electronic component to which the second portion 102 of the attachment portion 64 of the second support portion 52B is thermally connected may be of different types.

According to such a configuration, as in the first embodiment, improvement in heat dissipation of the semiconductor storage device 1F is achieved. Also, in the third embodiment, the second support portion 52B of the second cover member 50F is the second portion 102 (extension portion) that extends further in the X direction than the main body portion 51. When such a second portion 102 is provided, heat inside the housing 10 escapes more easily to the outside of the housing 10. Therefore, further improvement in heat dissipation of the semiconductor storage device 1F is achieved.

Preferred embodiments and modified examples have been described above. However, the embodiments and modified examples are not limited to the examples described above. For example, the preferred embodiments and modified examples described above may be realized in combination with each other. For example, the ordinal numbers (first, second, . . . ) assigned to the names of the members in the above description may be reassigned as appropriate.

According to at least one of the embodiments described above, a semiconductor storage device includes a housing, a board, a first electronic component, and a second electronic component. The board is in the housing and has a first surface. The first electronic component is mounted on the first surface. The second electronic component is mounted on the first surface. The second electronic component has a height larger than a height of the first electronic component from the first surface. The housing includes a first member and a second member. The first member has a first wall facing the first electronic component and an opening facing the second electronic component when viewed from a first direction. The first direction is a thickness direction of the board. The second member has a main body portion and a support portion. The main body portion covers the second electronic component at a position further away from the board than the first wall. The main body portion includes one or more protrusions protruding toward a side opposite to the second electronic component. The support portion is connected to the first member and supports the main body portion. With such a configuration, improvement in heat dissipation is achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a housing;
a board in the housing, the board having a first surface;
a first electronic component on the first surface; and
a second electronic component on the first surface, having a height larger than a height of the first electronic component from the first surface, wherein
the housing includes a first member and a second member,
the first member has a first wall and an opening, the first wall facing the first electronic component when viewed from a first direction, the opening facing the second electronic component when viewed from the first direction, the first direction being a thickness direction of the board,
the second electronic component has a main body portion and a support portion,
the main body portion covers the second electronic component at a position further away from the board than the first wall,
the main body portion includes one or more protrusions protruding toward a side opposite to the second electronic component, and
the support portion is connected to the first member and supports the main body portion.

2. The semiconductor storage device according to claim 1, wherein
each of the one or more protrusions extends in a third direction,
the third direction is intersecting the first direction and a second direction, and
the second direction is intersecting the first direction and in which the main body portion and the support portion are adjacent to each other.

3. The semiconductor storage device according to claim 1, wherein
the first member further includes a plurality of first fins, the plurality of first fins being on the first wall,
at least one of the one or more protrusions is between the plurality of first fins in the second direction intersecting the first direction.

4. The semiconductor storage device according to claim 3, wherein
a length in the first direction of the protrusion is larger than or equal to half a length in the first direction of one first fin included in the plurality of first fins.

5. The semiconductor storage device according to claim 1, wherein
the main body portion includes a cover portion,
the cover portion covers the second electronic component at a position further away from the board than the first wall,
the one or more protrusions are one or more second fins, and
the one or more second fins protrude from the cover portion to a side opposite to the second electronic component with respect to the cover portion.

6. The semiconductor storage device according to claim 1, wherein
the support portion includes an upright portion,
the upright portion passes through the opening, and
the upright portion is connected to the main body portion.

7. The semiconductor storage device according to claim 6, further comprising a third electronic component on the first surface, wherein
the first wall is thermally connected to the first electronic component via a first heat conductive member,
the support portion includes a heat receiving portion,
the heat receiving portion faces the third electronic component when viewed from the first direction, and
the heat receiving portion is thermally connected to the third electronic component via a second heat conductive member.

8. The semiconductor storage device according to claim 7, wherein
at least a part of the third electronic component faces the opening when viewed from the first direction, and
at least a part of the heat receiving portion is thermally connected to the third electronic component via the second heat conductive member at a position overlapping the opening when viewed from the first direction.

9. The semiconductor storage device according to claim 7, wherein
the heat receiving portion includes an extension portion,
the extension portion is larger than the main body portion in a third direction,
the third direction is intersecting the first direction and a second direction, and
the second direction is intersecting the first direction and in which the main body portion and the support portion are adjacent to each other.

10. The semiconductor storage device according to claim 9, wherein
the third electronic component faces the first wall when viewed from the first direction,
the extension portion is between the first wall and the third electronic component, and
the extension portion is thermally connected to the third electronic component via the second heat conductive member.

11. The semiconductor storage device according to claim 7, wherein the heat receiving portion is fixed to the first wall inside the housing.

12. The semiconductor storage device according to claim 11, further comprising a heat insulating member between the heat receiving portion and the first wall.

13. The semiconductor storage device according to claim 11, further comprising a third heat conductive member between the heat receiving portion and the first wall.

14. The semiconductor storage device according to claim 1, further comprising a fourth electronic component on the board, wherein
the fourth electronic component has a higher temperature during operation of the semiconductor storage device than the first electronic component,
the first wall includes a first region and a second region,
when viewed from the first direction, the first region faces the fourth electronic component, and the second region faces the first electronic component, and
the opening is between the first region and the second region in the first wall.

15. The semiconductor storage device according to claim 14, wherein
the opening has a first end adjacent to the first region, and
a gap is between the first end of the opening and the second member when viewed from the first direction.

16. The semiconductor storage device according to claim 1, wherein
the main body portion has a hole, and
at least a part of the second electronic component is inserted into the hole.

17. The semiconductor storage device according to claim 16, wherein
the main body portion includes a solid rectangular base portion, and
the hole is in the solid rectangular base portion.
